(19) United States
(12) Patent Application Publication
(10) Pub. No.: US 2025/0095984 A1
(43) Pub. Date: Mar. 20, 2025

(54) IN-SITU SIDEWALL PASSIVATION TOWARD THE BOTTOM OF HIGH ASPECT RATIO FEATURES

(71) Applicant: Applied Materials, Inc., Santa Clara, CA (US)

(72) Inventors: Sonam Dorje Sherpa, San Ramon, CA (US); Iljo Kwak, Santa Clara, CA (US); Kenji Takeshita, Sunnyvale, CA (US); Alok Ranjan, San Ramon, CA (US)

(73) Assignee: Applied Materials, Inc., Santa Clara, CA (US)

(21) Appl. No.: 18/370,536

(22) Filed: Sep. 20, 2023

(51) Int. Cl. H01L 21/02; H01L 21/306

(52) U.S. Cl. CPC H01L 21/02271; H01L 21/02208; H01L 21/30604

(57) ABSTRACT

Methods of semiconductor processing may include providing a silicon-containing precursor and an oxygen-containing precursor to a processing region of a semiconductor processing chamber. A substrate may be housed within the processing region. A feature may extend through one or more layers of material disposed on the substrate. The methods may include forming plasma effluents of the silicon-containing precursor and the oxygen-containing precursor. The methods may include contacting the substrate with the plasma effluents of the silicon-containing precursor and the oxygen-containing precursor. The contacting may form a silicon-and-oxygen-containing material on at least a bottom portion of the feature. A temperature in the processing region may be maintained at less than or about 0° C.

### TECHNICAL FIELD

The present technology relates to semiconductor systems and processes. More specifically, the present technology relates to sidewall passivation processes of high aspect ratio features.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

As aspect ratios of features being etched into materials continue to increase, the etching may not form a feature with uniform dimensions. To combat issues with profile control, passivation materials may be used to protect sidewalls of the existing feature during further etching. However, passivation materials may require additional processing operations and/or may clog the feature as aspect ratios continue to increase.

Thus, there is a need for improved systems and methods that can be used to produce high quality devices and structures. These and other needs are addressed by the present technology.

### SUMMARY

Methods of semiconductor processing may include providing a silicon-containing precursor and an oxygen-containing precursor to a processing region of a semiconductor processing chamber. A substrate may be housed within the processing region. A feature may extend through one or more layers of material disposed on the substrate. The methods may include forming plasma effluents of the silicon-containing precursor and the oxygen-containing precursor. The methods may include contacting the substrate with the plasma effluents of the silicon-containing precursor and the oxygen-containing precursor. The contacting may form a silicon-and-oxygen-containing material on at least a bottom portion of the feature. A temperature in the processing region may be maintained at less than or about 0° C.

In some embodiments, the silicon-containing precursor may further include a halogen. The silicon-containing precursor may be or include silicon tetrafluoride (SiF₄). The oxygen-containing precursor may be or include diatomic oxygen (O₂). The feature may be characterized by a depth of greater than or about 150 nm. The one or more layers of material may be or include alternating layers of oxygen-containing material and nitrogen-containing material. The plasma effluents of the silicon-containing precursor and the oxygen-containing precursor may be formed at a plasma power of less than or about 2,000 W. The methods may include applying a bias power while contacting the substrate with the plasma effluents of the silicon-containing precursor and the oxygen-containing precursor. The bias power may be less than or about 2,500 W. The methods may include, prior to providing the silicon-containing precursor and the oxygen-containing precursor to the processing region, etching the feature in the substrate.

Some embodiments of the present technology may encompass semiconductor processing methods. The methods may include providing a silicon-and-halogen-containing precursor and an oxygen-containing precursor to a processing region of a semiconductor processing chamber. A substrate may be housed within the processing region. A feature may extend through one or more layers of material disposed on the substrate. The methods may include forming plasma effluents of the silicon-and-halogen-containing precursor and the oxygen-containing precursor. The methods may include contacting the substrate with the plasma effluents of the silicon-and-halogen-containing precursor and the oxygen-containing precursor. The contacting may form a silicon-oxygen-and-halogen-containing material on at least a bottom portion of the feature.

In some embodiments, a flow rate ratio of the silicon-and-halogen-containing precursor relative to the oxygen-containing precursor may be greater than or about 10:1. A flow rate of the oxygen-containing precursor may be less than or about 25 sccm. The silicon-oxygen-and-halogen-containing material may be formed in the same semiconductor processing chamber in which the feature is etched. The silicon-oxygen-and-halogen-containing material may be physisorbed on the feature. A temperature in the processing region may be maintained at less than or about −20° C. A pressure in the processing region may be maintained at less than or about 100 mTorr.

Some embodiments of the present technology may encompass semiconductor processing methods. The methods may include providing one or more etchant precursors to a processing region of a semiconductor processing chamber. A substrate may be housed within the processing region. The substrate may include one or more layers of material. The methods may include contacting the substrate with the one or more etchant precursors. The contacting may etch a feature into the one or more layers of material. The methods may include halting a flow of the one or more etchant precursors. The methods may include providing a silicon-containing precursor and an oxygen-containing precursor to the processing region. The methods may include forming plasma effluents of the silicon-containing precursor and the oxygen-containing precursor. The methods may include contacting the substrate with the plasma effluents of the silicon-containing precursor and the oxygen-containing precursor. The contacting may form a passivation material on at least a bottom portion of the feature. A temperature in the processing region may be maintained at less than or about 0° C.

In some embodiments, the feature may be characterized by a depth of greater than or about 300 nm. The passivation material may be or include a silicon-oxygen-and-halogen-containing material.

Such technology may provide numerous benefits over conventional systems and techniques. For example, the processes may provide non-conformal passivation material that may be formed in-situ. Additionally, the passivation material may be formed at low temperatures to allow the passivation material to be physisorbed instead of chemisorbed which may prevent clogging of the opening of the features. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic top plan view of an exemplary processing system according to some embodiments of the present technology.

FIG. 2 shows a schematic cross-sectional view of an exemplary processing system according to some embodiments of the present technology.

FIG. 3 shows selected operations in a method of semiconductor processing according to some embodiments of the present technology.

FIGS. 4A-4C show schematic cross-sectional views of materials etched according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Passivating sidewalls while etching features, such as trenches or apertures, into one or more layers of material may maintain the profile throughout the depth of the feature being etched. The subsequent etch is ideally selective to the material being etched, and the passivation material is at least partially maintained during subsequent etching. To form passivation material, conventional processes may perform an ex-situ atomic layer deposition (ALD). However, these conventional processes require transferring the substrate to a separate tool, such as a separate semiconductor processing chamber. This ex-situ processing requires additional steps to the process flow, reduces throughput, and increases the cost of manufacturing. Other conventional processes have performed in-situ non-conformal passivation deposition. However, this deposition typically only protects a shallow portion of the feature and commonly results in clogging of an opening of the feature. The resultant clogging prevents etchant species and passivation species from penetrating the entire depth of the feature being etched.

The present technology overcomes these limitations by performing an in-situ formation of passivation material at reduced temperatures. By forming the passivation material at reduced temperatures, the passivation material may not be chemisorbed on sidewalls of the feature. Instead, the passivation material may be physisorbed and may diffuse towards a bottom of the feature. Accordingly, the present technology may break the conventional tradeoff between clogging and profile control.

Although the remaining disclosure will routinely identify specific etching and deposition processes utilizing the disclosed technology, it will be readily understood that the systems and methods are equally applicable to a variety of other processes as may occur in the described chambers. Accordingly, the technology should not be considered to be so limited as for use with the described etching and deposition processes alone. The disclosure will discuss one possible system and chamber that can be used with the present technology before describing systems and methods or operations of exemplary process sequences according to some embodiments of the present technology. It is to be understood that the technology is not limited to the equipment described, and processes discussed may be performed in any number of processing chambers and systems.

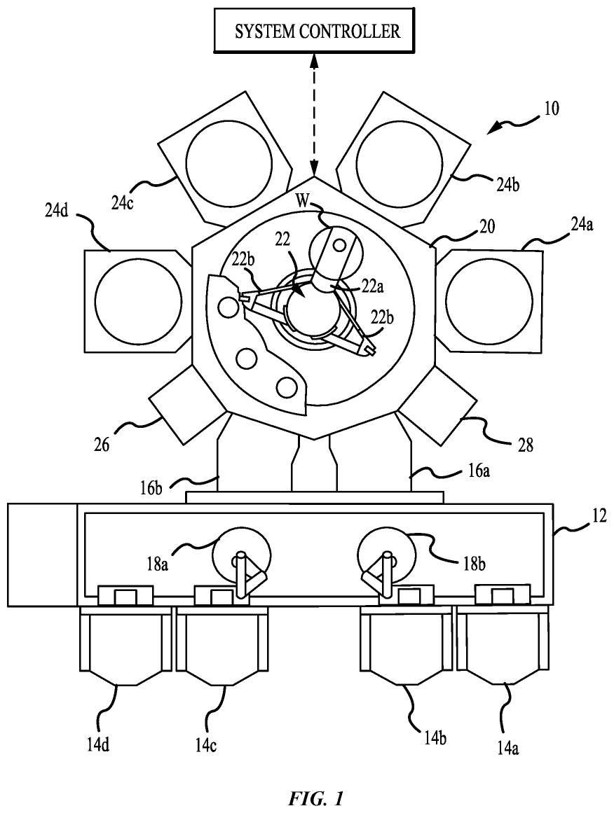

FIG. 1 shows a top plan view of one embodiment of a processing system 10 of deposition, etching, baking, and/or curing chambers according to embodiments. The tool or processing system 10 depicted in FIG. 1 may contain a plurality of process chambers, 24a-d, a transfer chamber 20, a service chamber 26, an integrated metrology chamber 28, and a pair of load lock chambers 16a-b. The process chambers may include any number of structures or components, as well as any number or combination of processing chambers.

To transport substrates among the chambers, the transfer chamber 20 may contain a robotic transport mechanism 22. The transport mechanism 22 may have a pair of substrate transport blades 22a attached to the distal ends of extendible arms 22b, respectively. The blades 22a may be used for carrying individual substrates to and from the process chambers. In operation, one of the substrate transport blades such as blade 22a of the transport mechanism 22 may retrieve a substrate W from one of the load lock chambers such as chambers 16a-b and carry substrate W to a first stage of processing, for example, a treatment process as described below in chambers 24a-d. The chambers may be included to perform individual or combined operations of the described technology. For example, while one or more chambers may be configured to perform a deposition or etching operation, one or more other chambers may be configured to perform a pre-treatment operation and/or one or more post-treatment operations described. Any number of configurations are encompassed by the present technology, which may also perform any number of additional fabrication operations typically performed in semiconductor processing.

If the chamber is occupied, the robot may wait until the processing is complete and then remove the processed substrate from the chamber with one blade 22a and may insert a new substrate with a second blade. Once the substrate is processed, it may then be moved to a second stage of processing. For each move, the transport mechanism 22 generally may have one blade carrying a substrate and one blade empty to execute a substrate exchange. The transport mechanism 22 may wait at each chamber until an exchange can be accomplished.

Once processing is complete within the process chambers, the transport mechanism 22 may move the substrate W from the last process chamber and transport the substrate W to a cassette within the load lock chambers 16a-b. From the load lock chambers 16a-b, the substrate may move into a factory interface 12. The factory interface 12 generally may operate to transfer substrates between pod loaders 14a-d in an atmospheric pressure clean environment and the load lock chambers 16a-b. The clean environment in factory interface 12 may be generally provided through air filtration processes, such as HEPA filtration, for example. Factory interface 12 may also include a substrate orienter/aligner that may be used to properly align the substrates prior to processing. At least one substrate robot, such as robots 18a-b, may be positioned in factory interface 12 to transport substrates between various positions/locations within factory interface 12 and to other locations in communication therewith. Robots 18a-b may be configured to travel along a track system within factory interface 12 from a first end to a second end of the factory interface 12.

The processing system 10 may further include an integrated metrology chamber 28 to provide control signals, which may provide adaptive control over any of the processes being performed in the processing chambers. The integrated metrology chamber 28 may include any of a variety of metrological devices to measure various film properties, such as thickness, roughness, composition, and the metrology devices may further be capable of characterizing grating parameters such as critical dimensions, sidewall angle, and feature height under vacuum in an automated manner.

Each of processing chambers 24a-d may be configured to perform one or more process steps in the fabrication of a semiconductor structure, and any number of processing chambers and combinations of processing chambers may be used on multi-chamber processing system 10. For example, any of the processing chambers may be configured to perform a number of substrate processing operations including any number of deposition processes including cyclical layer deposition, atomic layer deposition, chemical vapor deposition, physical vapor deposition, as well as other operations including etch, pre-clean, pre-treatment, post-treatment, anneal, plasma processing, degas, orientation, and other substrate processes. Some specific processes that may be performed in any of the chambers or in any combination of chambers may be metal deposition, surface cleaning and preparation, thermal annealing such as rapid thermal processing, and plasma processing. Any other processes may similarly be performed in specific chambers incorporated into multi-chamber processing system 10, including any process described below, as would be readily appreciated by the skilled artisan.

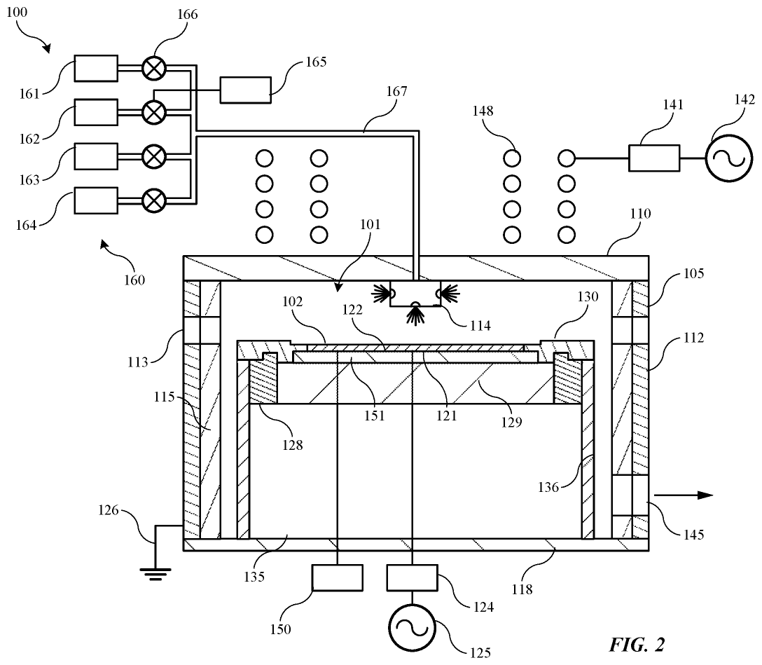

FIG. 2 illustrates a schematic cross-sectional view of an exemplary processing chamber 100 suitable for patterning a material layer disposed on a substrate 102 in the processing chamber 100. The exemplary processing chamber 100 is suitable for performing a patterning process, although it is to be understood that aspects of the present technology may be performed in any number of chambers, and substrate supports according to the present technology may be included in etching chambers, deposition chambers, treatment chambers, or any other processing chamber. The plasma processing chamber 100 may include a chamber body 105 defining a chamber volume 101 in which a substrate may be processed. The chamber body 105 may have sidewalls 112 and a bottom 118 which are coupled with ground 126. The sidewalls 112 may have a liner 115 to protect the sidewalls 112 and extend the time between maintenance cycles of the plasma processing chamber 100. The dimensions of the chamber body 105 and related components of the plasma processing chamber 100 are not limited and generally may be proportionally larger than the size of the substrate 102 to be processed therein. Examples of substrate sizes include 200 mm diameter, 250 mm diameter, 300 mm diameter and 450 mm diameter, among others, such as display or solar cell substrates as well.

The chamber body 105 may support a chamber lid assembly 110 to enclose the chamber volume 101. The chamber body 105 may be fabricated from aluminum or other suitable materials. A substrate access port 113 may be formed through the sidewall 112 of the chamber body 105, facilitating the transfer of the substrate 102 into and out of the plasma processing chamber 100. The access port 113 may be coupled with a transfer chamber and/or other chambers of a substrate processing system as previously described. A pumping port 145 may be formed through the sidewall 112 of the chamber body 105 and connected to the chamber volume 101. A pumping device may be coupled through the pumping port 145 to the chamber volume 101 to evacuate and control the pressure within the processing volume. The pumping device may include one or more pumps and throttle valves.

A gas panel 160 may be coupled by a gas line 167 with the chamber body 105 to supply process gases into the chamber volume 101. The gas panel 160 may include one or more process gas sources 161, 162, 163, 164 and may additionally include inert gases, non-reactive gases, and reactive gases, as may be utilized for any number of processes. Examples of process gases that may be provided by the gas panel 160 include, but are not limited to, hydrocarbon containing gas including methane, sulfur hexafluoride, silicon chloride, carbon tetrafluoride, hydrogen bromide, hydrocarbon containing gas, argon gas, chlorine, nitrogen, helium, or oxygen gas, as well as any number of additional materials. Additionally, process gasses may include nitrogen, chlorine, fluorine, oxygen, and hydrogen containing gases such as SiF₄, O₂, BCl₃, C₂F₄, C₄F₈, C₄F₆, CHF₃, CH₂F₂, CH₃F, NF₃, NH₃, CO₂, SO₂, CO, N₂, NO₂, N₂O, and H₂, among any number of additional precursors.

Valves 166 may control the flow of the process gases from the sources 161, 162, 163, 164 from the gas panel 160 and may be managed by a controller 165. The flow of the gases supplied to the chamber body 105 from the gas panel 160 may include combinations of the gases form one or more sources. The lid assembly 110 may include a nozzle 114. The nozzle 114 may be one or more ports for introducing the process gases from the sources 161, 162, 164, 163 of the gas panel 160 into the chamber volume 101. After the process gases are introduced into the plasma processing chamber 100, the gases may be energized to form plasma. An antenna 148, such as one or more inductor coils, may be provided adjacent to the plasma processing chamber 100. An antenna power supply 142 may power the antenna 148 through a match circuit 141 to inductively couple energy, such as RF energy, to the process gas to maintain a plasma formed from the process gas in the chamber volume 101 of the plasma processing chamber 100. Alternatively, or in addition to the antenna power supply 142, process electrodes below the substrate 102 and/or above the substrate 102 may be used to capacitively couple RF power to the process gases to maintain the plasma within the chamber volume 101. The operation of the power supply 142 may be controlled by a controller, such as controller 165, that also controls the operation of other components in the plasma processing chamber 100.

A substrate support pedestal 135 may be disposed in the chamber volume 101 to support the substrate 102 during processing. The substrate support pedestal 135 may include an electrostatic chuck 122 for holding the substrate 102 during processing. The electrostatic chuck (“ESC”) 122 may use the electrostatic attraction to hold the substrate 102 to the substrate support pedestal 135. The ESC 122 may be powered by an RF power supply 125 integrated with a match circuit 124. The ESC 122 may include an electrode 121 embedded within a dielectric body. The electrode 121 may be coupled with the RF power supply 125 and may provide a bias which attracts plasma ions, formed by the process gases in the chamber volume 101, to the ESC 122 and substrate 102 seated on the pedestal. The RF power supply 125 may cycle on and off, or pulse, during processing of the substrate 102. The ESC 122 may have an isolator 128 for the purpose of making the sidewall of the ESC 122 less attractive to the plasma to prolong the maintenance life cycle of the ESC 122. Additionally, the substrate support pedestal 135 may have a cathode liner 136 to protect the sidewalls of the substrate support pedestal 135 from the plasma gases and to extend the time between maintenance of the plasma processing chamber 100.

Electrode 121 may be coupled with a power source 150. The power source 150 may provide a chucking voltage of about 200 volts to about 2000 volts to the electrode 121. The power source 150 may also include a system controller for controlling the operation of the electrode 121 by directing a DC current to the electrode 121 for chucking and de-chucking the substrate 102. The ESC 122 may include heaters disposed within the pedestal and connected to a power source for heating the substrate, while a cooling base 129 supporting the ESC 122 may include conduits for circulating a heat transfer fluid to maintain a temperature of the ESC 122 and substrate 102 disposed thereon. The ESC 122 may be configured to perform in the temperature range required by the thermal budget of the device being fabricated on the substrate 102. For example, the ESC 122 may be configured to maintain the substrate 102 at a temperature of about −150° C. or lower to about 500° C. or higher depending on the process being performed.

The cooling base 129 may be provided to assist in controlling the temperature of the substrate 102. To mitigate process drift and time, the temperature of the substrate 102 may be maintained substantially constant by the cooling base 129 throughout the time the substrate 102 is in the cleaning chamber. In some embodiments, the temperature of the substrate 102 may be maintained throughout subsequent cleaning processes at temperatures between about −150° C. and about 500° C., although any temperatures may be utilized. A cover ring 130 may be disposed on the ESC 122 and along the periphery of the substrate support pedestal 135. The cover ring 130 may be configured to confine etching gases to a desired portion of the exposed top surface of the substrate 102, while shielding the top surface of the substrate support pedestal 135 from the plasma environment inside the plasma processing chamber 100. Lift pins may be selectively translated through the substrate support pedestal 135 to lift the substrate 102 above the substrate support pedestal 135 to facilitate access to the substrate 102 by a transfer robot or other suitable transfer mechanism as previously described.

The controller 165 may be utilized to control the process sequence, regulating the gas flows from the gas panel 160 into the plasma processing chamber 100, and other process parameters. Software routines, when executed by the CPU, transform the CPU into a specific purpose computer such as a controller, which may control the plasma processing chamber 100 such that the processes are performed in accordance with the present disclosure. The software routines may also be stored and/or executed by a second controller that may be associated with the plasma processing chamber 100.

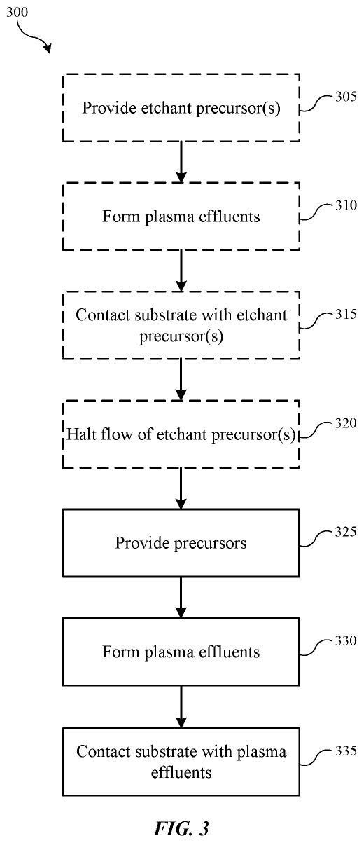

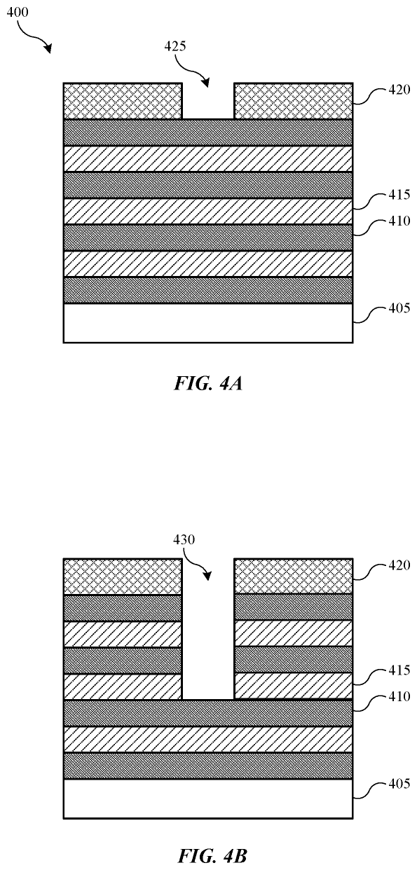

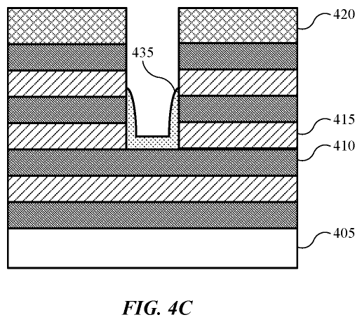

The chamber discussed previously may be used in performing exemplary methods, including etching and deposition methods. Turning to FIG. 3 is shown exemplary operations in a method 300 according to embodiments of the present technology. Method 300 may include one or more operations prior to the initiation of the method, including front end processing, deposition, etching, polishing, cleaning, or any other operations that may be performed prior to the described operations. The method 300 may include a number of optional operations, which may or may not be specifically associated with some embodiments of methods according to embodiments of the present technology. For example, many of the operations are described in order to provide a broader scope of the processes performed, but are not critical to the technology, or may be performed by alternative methodology as will be discussed further below. Method 300 may describe operations shown schematically in FIGS. 4A-4C, the illustrations of which will be described in conjunction with the operations of method 300. It is to be understood that the figures illustrate only partial schematic views, and a substrate may contain any number of additional materials and features having a variety of characteristics and aspects as illustrated in the figures.

Method 300 may or may not involve optional operations to develop the semiconductor structure to a particular fabrication operation. It is to be understood that method 300 may be performed on any number of semiconductor structures 400 or substrates 405, as illustrated in FIG. 4A, including exemplary structures on which a passivation material deposition operation may be performed. Exemplary semiconductor structures may include a trench, via, or other recessed features that may include one or more exposed materials. For example, an exemplary substrate may contain silicon or some other semiconductor substrate material as well as interlayer dielectric materials through which a recess, trench, via, or isolation structure may be formed. One or more layers of material may be disposed on the substrate. For example, exposed materials at any time during the process may be or include one or more dielectric materials, a contact material, a transistor material, or any other material that may be used in semiconductor processes.

For example, as illustrated in FIG. 4A, alternating layers of a first layer of material 410 and a second layer of material 415 may overlie the substrate 405. Substrate 405 may be any number of materials used in semiconductor processing. The substrate 405 material may be or include silicon, germanium, dielectric materials including silicon oxide or silicon nitride, metal materials, or any number of combinations of these materials, which may be the substrate 405, or materials formed in structure 400. In the structure 400 shown in FIG. 4A, the first layer of material 410 may be an oxygen-containing material, such as silicon-and-oxygen-containing material (e.g., silicon oxide). The second layer of material 415 may be a nitrogen-containing material, such as silicon-and-nitrogen-containing material (e.g., silicon nitride). Any number of pairs of the first layer of material 410 and the second layer of material 415 may be present on the substrate. A hardmask material 420 may overlie the alternating layers of the first layer of material 410 and the second layer of material 415. The hardmask material 420 may be patterned to include an aperture 425. The aperture 425 may expose underlying material, such as the first layer of material 410 or the second layer of material 415.

It is to be understood that any number of additional materials may be formed in the structure 400 illustrated. It is to be understood that the noted structure is not intended to be limiting, and any of a variety of other semiconductor structures are similarly encompassed. Other exemplary structures may include two-dimensional and three-dimensional structures common in semiconductor manufacturing, and within which a passivation material is needed to maintain dimensions and profile of a feature being etched through one or more layers disposed on the substrate. For example, while the present technology discusses the first layer of material 410 or the second layer of material 415 being disposed on the substrate 405, any other material, such as a carbon-containing material, may benefit from the passivation material deposition of the present technology. Additionally, although a high aspect ratio structure may benefit from the present technology, the technology may be equally applicable to lower aspect ratios and any other structures.

As illustrated in FIG. 4B, method 300 may include optional operations to etch a feature into the one or more layers of material disposed on the substrate 405, such as the first layer of material 410 or the second layer of material 415. For example, method 300 may include providing one or more etchant precursors to a processing region of a semiconductor processing chamber at optional operation 305. The etchant precursors may include, for example, a halogen-containing precursor and a hydrogen-containing precursor. In embodiments, the halogen-containing precursor may be a fluorine-containing precursor such as nitrogen trifluoride (NF₃).

The hydrogen-containing precursor may be, for example, diatomic hydrogen (H₂). Plasma effluents of the halogen-containing precursor and the hydrogen-containing precursor may be formed at optional operation 310. At optional operation 315, the substrate 405 may be contacted with the one or more etchant precursors or plasma effluents thereof. The contacting may etch the feature 430 into the one or more layers of material on the substrate, such as the first layer of material 410 or the second layer of material 415. While only one feature 430 is illustrated in FIG. 4B, any number of features may be etched across the structure 400.

An aspect ratio or the height-to-width ratio of the feature 430 may be greater than or about 2:1, greater than or about 3:1, greater than or about 5:1, greater than or about 10:1, greater than or about 20:1, or greater. The feature 430 may be characterized by a depth of greater than or about 150 nm, and may be characterized by a depth of greater than or about 200 nm, greater than or about 250 nm, greater than or about 300 nm, greater than or about 350 nm, greater than or about 400 nm, greater than or about 450 nm, greater than or about 500 nm, greater than or 550 nm, or more.

To maintain the profile of the feature 430 during subsequent etching, a passivation material may be deposited within the feature 430. In conventional technologies, a conformal liner may be deposited using atomic layer deposition (ALD). However, ALD may require a different semiconductor processing chamber and the conformal liner may be deposited ex-situ. The transfer of the substrate between different semiconductor processing chambers may reduce queue times and increase throughput. Additional conventional technologies may perform an in-situ non-conformal deposition, but these conventional depositions may result in clogging towards the top of the features, such as at an opening of the features, and/or limited or no passivation at the bottom of the features. These conventional in-situ non-conformal depositions may form passivation materials that are chemisorbed and not able to reach lower portions of the features. Conversely, the present technology, as further discussed below, may provide a passivation material that may be physisorbed on surfaces defining the feature 430 in-situ, which may allow the passivation material to diffuse to a bottom of the feature 430 and/or etch front of the feature 430.

After halting a flow of the one or more etchant precursors at optional operation 320, method 300 may include providing one or more deposition precursors into the processing region of the semiconductor processing chamber at operation 325. The one or more deposition precursors may include a silicon-containing precursor and a hydrogen-containing precursor. Plasma effluents of the one or more precursors may be formed at operation 330. The plasma effluents of the one or more deposition precursors, such as the silicon-containing precursor and the hydrogen-containing precursor, may contact the substrate 405 including the first layer of material 410 and the second layer of material 415 exposed in the feature 430. As illustrated in FIG. 4C, the contacting may form a passivation material 435 in the feature 430. The passivation material 435 may be or include a silicon-containing material, such as a silicon-and-oxygen-containing material or a silicon-oxygen-and-halogen-containing material.

As previously discussed, the precursors used during method 300 and provided at operation 305 may include a silicon-containing precursor and an oxygen-containing precursor. In embodiments, the silicon-containing precursor may further include a halogen. The halogen may be, but is not limited to, fluorine. Non-limiting silicon-containing precursors may be or include silane (SiH₄), disilane (Si₂H₆), silicon tetrafluoride (SiF₄), silicon tetrachloride (SiCl₄), or any other silicon-containing material. Additionally, non-limiting oxygen-containing precursors may include diatomic oxygen (O₂), water (H₂O), hydrogen peroxide (H₂O₂), or any other oxygen-containing material. In embodiments, one or more inert precursors or carrier gases may be provided with the silicon-containing precursor and the oxygen-containing precursor. Exemplary inert precursors or carrier gases may include one or more of argon, xenon, or helium in some embodiments, as well as any other non-reactive material.

In embodiments, a flow rate of the silicon-containing precursor may be greater than a flow rate of the oxygen-containing precursor. For example, a flow rate ratio of the silicon-containing precursor relative to the oxygen-containing precursor may be greater than or about 10:1, and a flow rate ratio of the silicon-containing precursor relative to the oxygen-containing precursor may be greater than or about 11:1, greater than or about 12:1, greater than or about 13:1, greater than or about 14:1, greater than or about 15:1, greater than or about 16:1, greater than or about 17:1, greater than or about 18:1, greater than or about 20:1, greater than or about 25:1, greater than or about 30:1, greater than or about 35:1, or higher. The increased flow rate of the silicon-containing precursor may dilute the oxygen-containing precursor, which may inadvertently oxidize other materials disposed on the substrate 405.

In embodiments, a flow rate of the silicon-containing precursor may be greater than or about 50 sccm, and may be greater than or about 75 sccm, greater than or about 100 sccm, greater than or about 125 sccm, greater than or about 150 sccm, greater than or about 160 sccm, greater than or about 170 sccm, greater than or about 180 sccm, greater than or about 190 sccm, or more. In embodiments, a flow rate of the oxygen-containing precursor may be less than or about 25 sccm, and may be less than or about 20 sccm, less than or about 15 sccm, less than or about 10 sccm, less than or about 9 sccm, less than or about 8 sccm, less than or about 7 sccm, less than or about 6 sccm, less than or about 5 sccm, or less.

The plasma effluents of the silicon-containing precursor and the oxygen-containing precursor may be formed at a plasma power of less than or about 2,500 W, and may be formed at a plasma power of less than or about 2,250 W, less than or about 2,000 W, less than or about 1,750 W, less than or about 1,500 W, less than or about 1,250 W, less than or about 1,000 W, less than or about 750 W, less than or 500 W, or less. At higher plasma powers, deposition rate may increase and precise control of the deposition of passivation material 435 may decrease.

In embodiments, the method 200 may include applying a bias power while contacting the substrate 405 with the plasma effluents of the silicon-containing precursor and the oxygen-containing precursor. The bias power may sputter passivation material 435 at the bottom of the feature 430, leaving passivation material only on the sidewalls of the feature 430. To limit the sputtering to the passivation material 435 and to minimize damage to other materials of the structure 400, the bias power may be less than or about 2,500 W, and may be less than or about 2,250 W, less than or about 2,000 W, less than or about 1,750 W, less than or about 1,500 W, less than or about 1,250 W, less than or about 1,000 W, less than or about 750 W, less than or 500 W, or less.

As illustrated in FIG. 4C, the contacting at operation 335 may deposit the passivation material 435 in the feature 430. Depending on the deposition precursors provided to the processing region, the passivation material may be a silicon-containing material, such as a silicon-and-oxygen-containing material or a silicon-oxygen-and-halogen-containing material. While shown as covering the etch front of the feature 430, the application of bias power, as previously discussed, may sputter the passivation material 435 from the etch front. In embodiments, as previously discussed, the passivation material 435, such as the silicon-oxygen-and-halogen-containing material, may be formed in the same semiconductor processing chamber in which the feature 430 is etched.

Processing conditions may impact and facilitate the deposition according to the present technology. For example, the temperature at which the operations are performed may impact the location of the formation of the passivation material 435. During the contacting of the substrate 405 with the plasma effluents, reduced temperatures may facilitate physisorption and prevent chemisorption of the passivation material 435. By preventing chemisorption, the passivation material 435 may diffuse to the bottom of the feature 430 which may prevent clogging of the opening of the feature 430. Accordingly, in some embodiments of the present technology, the method 300 may be performed at substrate, pedestal, and/or chamber temperatures less than or about 50° C., and may be performed at temperatures less than or about 25° C., less than or about 0° C., less than or about −10° C., less than or about −20° C., less than or about −30° C., less than or about −40° C., less than or about −50° C., less than or about −60° C., less than or about −70° C., less than or about −80° C., less than or about −90° C., less than or about −100° C., or less. The temperature may also be maintained at any temperature within these ranges, within smaller ranges encompassed by these ranges, or between any of these ranges.

The pressure within the processing region of the semiconductor processing chamber may also affect the operations performed. To facilitate the deposition of passivation material 435, a processing pressure may be less than or about 100 mTorr, and may be maintained at less than or about 80 mTorr, less than or about 60 mTorr, less than or about 40 mTorr, less than or about 20 m Torr, less than or about 15 mTorr, less than or about 10 mTorr, or less. The pressure may also be maintained at any pressure within these ranges, within smaller ranges encompassed by these ranges, or between any of these ranges.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the material” includes reference to one or more materials and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a silicon-containing precursor and an oxygen-containing precursor to a processing region of a semiconductor processing chamber, wherein a substrate is housed within the processing region, and wherein a feature extends through one or more layers of material disposed on the substrate;
forming plasma effluents of the silicon-containing precursor and the oxygen-containing precursor; and
contacting the substrate with the plasma effluents of the silicon-containing precursor and the oxygen-containing precursor, wherein the contacting forms a silicon-and-oxygen-containing material on at least a bottom portion of the feature, and wherein a temperature in the processing region is maintained at less than or about 0° C.

2. The semiconductor processing method of claim 1, wherein the silicon-containing precursor further comprises a halogen.

3. The semiconductor processing method of claim 1, wherein the silicon-containing precursor comprises silicon tetrafluoride (SiF₄).

4. The semiconductor processing method of claim 1, wherein the oxygen-containing precursor comprises diatomic oxygen (O₂).

5. The semiconductor processing method of claim 1, wherein the feature is characterized by a depth of greater than or about 150 nm.

6. The semiconductor processing method of claim 1, wherein the one or more layers of material comprise alternating layers of oxygen-containing material and nitrogen-containing material.

7. The semiconductor processing method of claim 1, wherein the plasma effluents of the silicon-containing precursor and the oxygen-containing precursor are formed at a plasma power of less than or about 2,000 W.

8. The semiconductor processing method of claim 1, further comprising:
applying a bias power while contacting the substrate with the plasma effluents of the silicon-containing precursor and the oxygen-containing precursor.

9. The semiconductor processing method of claim 8, wherein the bias power is less than or about 2,500 W.

10. The semiconductor processing method of claim 1, further comprising:
prior to providing the silicon-containing precursor and the oxygen-containing precursor to the processing region, etching the feature in the substrate.

11. A semiconductor processing method comprising:
providing a silicon-and-halogen-containing precursor and an oxygen-containing precursor to a processing region of a semiconductor processing chamber, wherein a substrate is housed within the processing region, and wherein a feature extends through one or more layers of material disposed on the substrate;
forming plasma effluents of the silicon-and-halogen-containing precursor and the oxygen-containing precursor; and
contacting the substrate with the plasma effluents of the silicon-and-halogen-containing precursor and the oxygen-containing precursor, wherein the contacting forms a silicon-oxygen-and-halogen-containing material on at least a bottom portion of the feature.

12. The semiconductor processing method of claim 11, wherein a flow rate ratio of the silicon-and-halogen-containing precursor relative to the oxygen-containing precursor is greater than or about 10:1.

13. The semiconductor processing method of claim 11, wherein a flow rate of the oxygen-containing precursor is less than or about 25 sccm.

14. The semiconductor processing method of claim 11, wherein the silicon-oxygen-and-halogen-containing material is formed in the same semiconductor processing chamber in which the feature is etched.

15. The semiconductor processing method of claim 11, wherein the silicon-oxygen-and-halogen-containing material is physisorbed on the feature.

16. The semiconductor processing method of claim 11, wherein a temperature in the processing region is maintained at less than or about −20° C.

17. The semiconductor processing method of claim 11, wherein a pressure in the processing region is maintained at less than or about 100 mTorr.

18. A semiconductor processing method comprising:
providing one or more etchant precursors to a processing region of a semiconductor processing chamber, wherein a substrate is housed within the processing region, and wherein the substrate comprises one or more layers of material;
contacting the substrate with the one or more etchant precursors, wherein the contacting etches a feature into the one or more layers of material;
halting a flow of the one or more etchant precursors;
providing a silicon-containing precursor and an oxygen-containing precursor to the processing region;
forming plasma effluents of the silicon-containing precursor and the oxygen-containing precursor; and
12 contacting the substrate with the plasma effluents of the silicon-containing precursor and the oxygen-containing precursor, wherein the contacting forms a passivation material on at least a bottom portion of the feature, and wherein a temperature in the processing region is maintained at less than or about 0° C.

19. The semiconductor processing method of claim 18, wherein the feature is characterized by a depth of greater than or about 300 nm.

20. The semiconductor processing method of claim 18, wherein the passivation material comprises a silicon-oxygen-and-halogen-containing material.
